(19) United States
(12) Patent Application Publication
(10) Pub. No.: US 2015/0060433 A1
(43) Pub. Date: Mar. 5, 2015

(54) HIGH TEMPERATURE PLATEN POWER CONTACT

(71) Applicant: Varian Semiconductor Equipment Associates, Inc., Gloucester, MA (US)

(72) Inventors: Aaron P. Webb, Austin, TX (US); Paul Forderhase, Austin, TX (US); Paul E. Pergande, Austin, TX (US)

(73) Assignee: Varian Semiconductor Equipment Associates, Inc., Gloucester, MA (US)

(21) Appl. No.: 14/013,722

(22) Filed: Aug. 29, 2013

(51) Int. Cl. H01L 21/67; H01R 13/533

(52) U.S. Cl. CPC H01L 21/67103; H01R 13/533
USPC 219/444.1; 439/487

(57) ABSTRACT

A heated platen having a heating element and an electrical contact assembly for the heating element is generally described. Various examples provide a dielectric plate including a heating element and a terminal disposed therein. An electrical connection assembly configured to connect the heating element to a power source is also provided. The electrical connection including an electrical connection plug, a conductive sleeve disposed within the electrical connection plug, and a connector pin having a bottom portion and a top portion, the bottom portion disposed within the sleeve, the top portion having a spring structure, the spring structure configured to maintain electric contact with the terminal throughout a range of temperatures.

### FIELD OF THE DISCLOSURE

Embodiments of the present disclosure generally relate to the field of substrate processing, and more particularly to high temperature platens and power contacts used to support a substrate during semiconductor device manufacturing.

### BACKGROUND OF THE DISCLOSURE

Ion implantation is a process of depositing chemical species into a substrate by direct bombardment of the substrate with energized ions. In semiconductor manufacturing, ion implanters are used primarily for doping processes that alter the type and level of conductivity of target materials. A precise doping profile in an integrated circuit (IC) substrate and its thin-film structure is important for proper IC performance. To achieve a desired doping profile, one or more ion species may be implanted in different doses and at different energies.

In some ion implantations processes, the desired doping profile is achieved by implanting ions in the target substrate at high temperatures (e.g., between 150-600° Celsius.) Heating the target substrate can be achieved by supporting the substrate on a heated platen during the ion implant process. A typical heated platen may include one or more heating elements connected to a power source via electrical contacts. During operation, these electrical contacts are subjected to stresses associated with high temperature operation. In addition, these electrical contacts may absorb some of the heat from the heating element, effectively acting as small heat sinks that can reduce the temperature of the heated platen in areas adjacent to the electrical contacts. As will be appreciated, any temperature variation between portions of the heated platen may be affect the uniformity of the heat transferred to the target substrate. As a result, the target substrate may have sections that are heated to different temperatures, which may adversely affect the ion implantation process. In some instances, the heated platen can warp or bow as it is heated, and it would be desirable to provide electrical contacts that can provide consistent electrical contact with a power source even when the heated platen is not completely flat.

In view of the foregoing, it will be understood that there is a need to ensure that electrical contacts for heated platens operate sufficiently at high temperatures, have low thermal conductivity, and maintain electrical contact throughout out a range of operating temperatures.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In general, various embodiments of the present disclosure provide an electrical connection assembly for use in a heated platen having a dielectric plate with a heating element and a terminal electrically connected to the heating element disposed therein. The assembly can include an electrical connection plug, and a connector pin having a bottom portion and a top portion. The bottom portion can be configured for electrically coupling to the electrical connection plug. The top portion can have a spring structure configured to maintain electric contact with the terminal of the heated platen by biasing the top portion against the terminal.

Some embodiments disclose an electrical connection assembly for use in a heated platen having a dielectric plate with a heating element and a terminal electrically connected to the heating element disposed therein. The assembly may include an electrical connection plug, a conductive sleeve disposed within the electrical connection plug, and a connector pin having a bottom portion and a top portion. The bottom portion may be disposed within the conductive sleeve. The top portion may have a spring structure. The spring structure may be configured to maintain electric contact with the terminal throughout a range of temperatures.

Some embodiments include a heated platen comprising a dielectric plate having a heating element and a terminal disposed therein. The terminal may provide electrical contact to the heating element. An electrical connection assembly may be configured to connect the heating element to a power source. The electrical connection assembly may include an electrical connection plug, a conductive sleeve disposed within the electrical connection plug, and a connector pin having a bottom portion and a top portion. The bottom portion may be disposed within the sleeve. The top portion may have a spring structure. The spring structure may be configured to maintain electric contact with the terminal throughout a range of temperatures.

### BRIEF DESCRIPTION OF THE DRAWINGS

By way of example, various embodiments of the disclosed device will now be described, with reference to the accompanying drawings, in which:

FIGS. 1A-1B are block diagrams of an exemplary substrate support platen;

FIG. 2 is a block diagram of a portion of an exemplary heated platen;

FIG. 3 is a block diagram of a portion of another exemplary heated platen;

FIG. 4 is a block diagram of a portion of a further exemplary heated platen;

FIGS. 5A-5C are isometric, and first and second side view of an exemplary connector pin for use with a heated platen according to one or more embodiments of the disclosure;

FIG. 6 is a block diagram of another exemplary connector pin for use with a heated platen according to one or more embodiments of the disclosure; and

FIGS. 7A and 7B are isometric and side views, respectively, of a further exemplary connector pin for use with a heated platen according to one or more embodiments of the disclosure.

### DETAILED DESCRIPTION

Embodiments of the present disclosure provide for electrical contact between a power source and a heated platen. During operation, as the temperature of the heated platen is increased, the electrical contacts described herein may provide for robust operation at the high operating temperatures. Furthermore, the electrical contacts described herein may have a relatively low thermal conductivity, so that a minimum amount of heat from the heated platen may be absorbed by the electrical contacts. As will be appreciated, the electrical contacts described herein may be implemented in a heated platen which may be used to support a substrate during processing. For example, the heated platen may be used to support a substrate during an ion implant process, a plasma deposition process, an etching process, a chemical mechanical planarization process, or generally any process where a semiconductor substrate is to be supported on a heated platen. As such, an example heated platen is described. It will be appreciated however, that the embodiments of the present disclosure are not limited by the described example heated platen and may find application in any of a variety of platen applications used in a variety of semiconductor manufacturing processes.

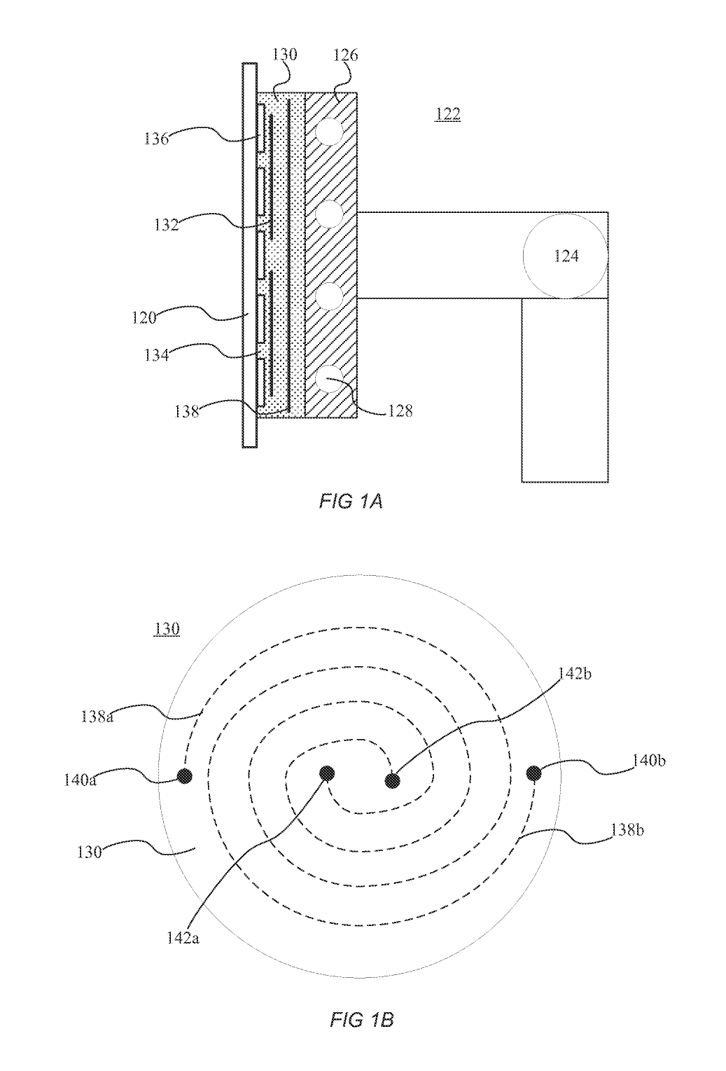

FIG. 1A illustrates a block diagram showing a cut-away view of a heated platen 122. As depicted, the heated platen 122 may be coupled to a scanner mechanism 124 that facilitates various angular and/or rotational movements of the platen 122. The platen 122 may comprise a dielectric plate 130 and an interface plate 126. The dielectric plate 130 may have electrodes 132 embedded therein to apply an electrostatic force to hold the substrate 120 onto a surface of the dielectric plate 130. The surface of the dielectric plate 130 may either be smooth or it may contain mesa structures 134 to reduce backside contact to the substrate 120 and to reduce the generation of backside particles. One or more interface regions 136 may be formed between the substrate 120 and the dielectric plate 130. These interface regions may, in some embodiments, contain a backside gas to improve or adjust thermal contact between the substrate 120 and the dielectric plate 130.

One or more heating elements 138 may be embedded in the dielectric plate 130 to heat the dielectric plate 130 and to maintain the heated platen 122 at a desired temperature or within a desired temperature range. In some embodiments the heating elements may comprise an electrically conductive material. During operation, to heat the substrate 120 the heating elements 138 may be activated, as will be described in greater detail below. In some examples, the heating elements 138 may be configured to heat the dielectric layer 130 to a temperature of between 150 and 600° C. In some embodiments the interface plate 126 may include cooling passages 128, through which a cooling fluid may be passed to cool the heated platen 122 back down to, or below, room temperature.

FIG. 1B illustrates a block diagram showing a top view of the dielectric plate 130. As depicted, the dielectric plate 130 includes heating elements 138a and 138b. As noted above, the dielectric plate 130 also includes electrodes 132 configured to hold the substrate 120 on the dielectric plate 130 via static electricity. These electrodes 132 are not shown in FIG. 1B for clarity. Furthermore, although the dielectric plate 130 is shown having two heating elements (e.g., 138a and 138b,) it will be appreciated that in practice, the dielectric plate 130 may have greater or fewer heating elements, as desired. The heating elements 138a, 138b include terminals 140a, 142a and 140b, 142b respectively. During operation, electric current may be passed through the heating elements 138a, 138b by applying a voltage potential to the terminals 140a, 142a and 140b, 142b. As a result of the current passing through the heating elements 138a, 138b, the temperature of the heating elements will increase. This temperature increase may be thermally conducted through the dielectric plate 130 to the substrate 120. In some examples, the dielectric plate 130 may be formed from a ceramic material having a low dielectric constant. The heating elements 138a, 138b may be formed from a thick film paste, such as, for example, silver palladium.

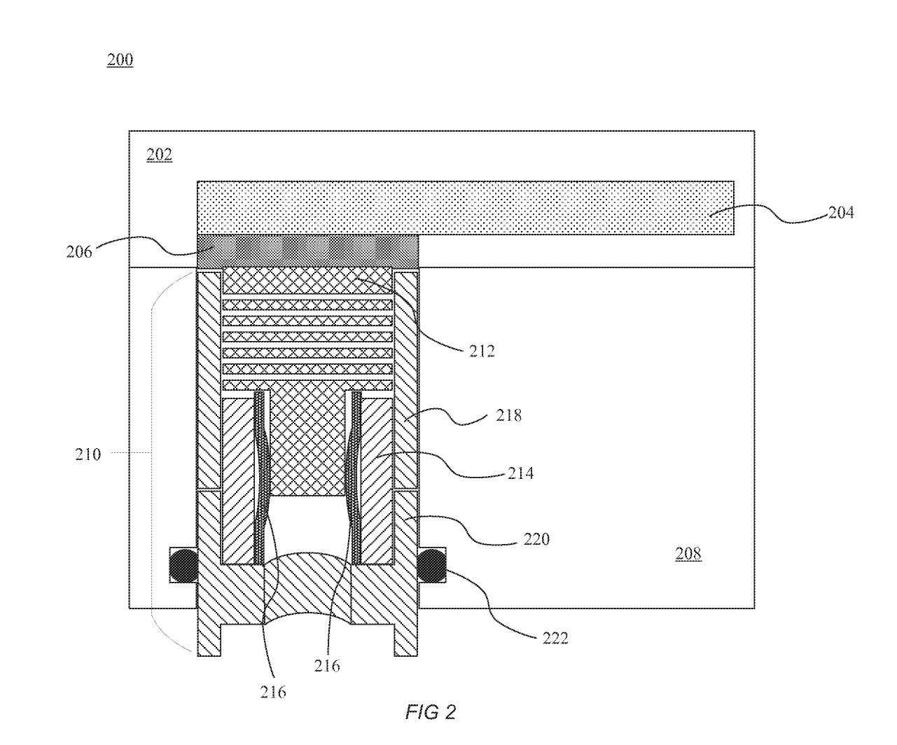

FIG. 2 illustrates a block diagram showing a cutaway view of a portion of an exemplary heated platen 200. The heated platen 200 of this embodiment may be the same as or similar to the heated platen 122 described in relation to FIGS. 1A-1B. As depicted, the heated platen 200 includes a dielectric plate 202 having a heating element 204 and a corresponding terminal 206 disposed therein. The dielectric plate 202 is disposed on an interface plate 208. An electrical contact assembly 210 is disposed within the interface plate 208 and provides electrical connection between a power supply (via electrical connection plug 220) and the terminal 206. It is to be appreciated that FIG. 2 illustrates only a portion of the heated platen 200. More specifically, only a single terminal (i.e., terminal 206) is shown. It will be appreciated that the heated platen 200 will also include a second terminal and a corresponding electrical contact assembly (both not shown for purposes of clarity) to complete a heating circuit between the terminals. Furthermore, the heated platen 200 may include additional heating element(s), corresponding terminals and electrical contact assemblies, to achieve a desired heating capacity for the heated platen 200. It will also be appreciated that the heated platen 200 may include electrodes, for example, which can be used to electrostatically clamp a substrate to the heated platen in the manner described above with respect to FIG. 1B. Such electrodes are also not shown in the current view for purposes of clarity.

As depicted, the electrical contact assembly 210 includes a connector pin 212, a conductive sleeve 214, a banana clip 216, a nonconductive sleeve 218, an electrical connection plug 220 and an O-ring 222. In general, the electrical contact assembly 210 is arranged to allow the conduction of electric current from the electrical connection plug 220 to the connector pin 212 and the terminal 206. The current may be conducted from the electrical connection plug 220 through the conductive sleeve 214, the banana clip 216 and the connector pin 212. The connector pin 212 may have various geometries, which will be described in greater detail below. The nonconductive sleeve 218 may be formed from a material having high dielectric properties (e.g., alumina, or the like,) in order to prevent or suppress arcing. The O-ring 222 may be provided to seal the electrical connection plug 220 to the interface plate 208. As depicted, the O-ring 222 may fit within a recess formed in the interface plate 208.

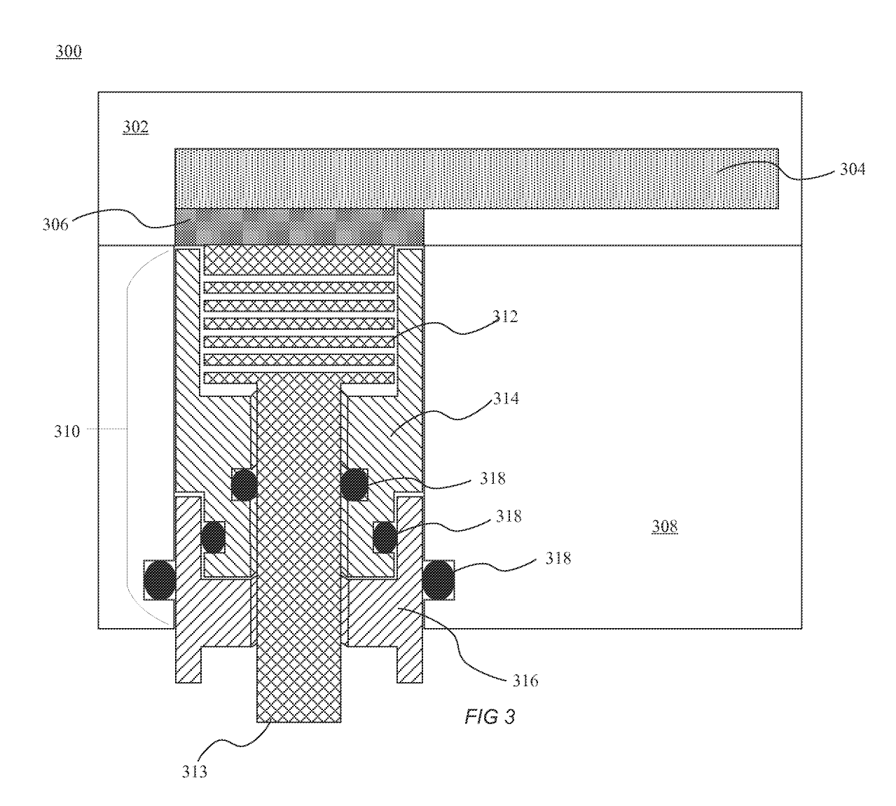

FIG. 3 illustrates a block diagram showing a cut-away view of another example heated platen 300. The heated platen 300 of this embodiment may be the same or similar to the heated platens previously described in relation to FIGS. 1A-2. As depicted, the heated platen 300 includes a dielectric plate 302 having a heating element 304 and a corresponding terminal 306 disposed therein. The dielectric plate 302 is disposed on an interface plate 308. An electrical contact assembly 310 is disposed within the interface plate 308 and provides electrical connection to the terminal 306. It will be appreciated, that FIG. 3 illustrates only a portion of the heated platen 300. More specifically, only a single terminal (i.e., terminal 306) is shown. It will be appreciated that heated platen 300 will include a second terminal and a corresponding electrical contact assembly (both not shown for purposes of clarity). Furthermore, the heated platen 300 may include additional heating element(s), corresponding terminals and electrical contact assemblies to provide a desired heating capacity to the heated platen. It will also be appreciated that the heated platen 300 may include electrodes, for example, which can be used to electrostatically clamp a substrate to the heated platen in the manner described above with respect to FIG. 1B. Such electrodes are also not shown in the current view for purposes of clarity.

As depicted, the electrical contact assembly 310 includes a connector pin 312, a non-conductive sleeve 314, a connection plug 316 and a plurality of O-rings 318 for sealing the elements of the electrical contact assembly together and to the interface plate 308. As can be seen, the non-conductive sleeve 314 surrounds the connector pin 312 along and extends upward toward the terminal 306, thus forming an insulating sleeve around the connector pin 312 to prevent arcing during operation. In general, the electrical contact assembly 310 is arranged to allow the conduction of electric current to the terminal 306 through the connector pin 312. In some applications, current may be conducted from the connection plug 316 directly to the connector pin 312. In such embodiments, a layer of dielectric or other insulating material may be provided between the connection plug 316 and the interface plate 308. In some embodiments, the connection plug 316 is non-conductive. In such applications, the connector pin 312 may be connected to a current source via the bottom portion 313 of the connector pin. In further applications, the non-conductive element 314 and the connection plug 316 may be formed from the same non-conductive material (e.g., ceramic, dielectric, or the like) and even may be formed as a single component.

The connector pin 312 may have various geometries, which will be described in greater detail below. The O-rings 318 may be provided to seal the electrical connection plug 316 to the interface plate 308, seal the non-conductive sleeve 314 to the electrical connection plug 316 and seal the connector pin 312 to the non-conductive sleeve 314. As depicted, the plurality of O-rings 318 may fit within corresponding recesses in the interface plate 308 and the various components of the electrical contact assembly. In some embodiments, the non-conductive sleeve 314 may be affixed (e.g., crimped, soldered, welded, bonded, or the like) to the bottom portion 313 of the connector pin 312. In such cases the O-ring 318 between the two pieces may be eliminated.

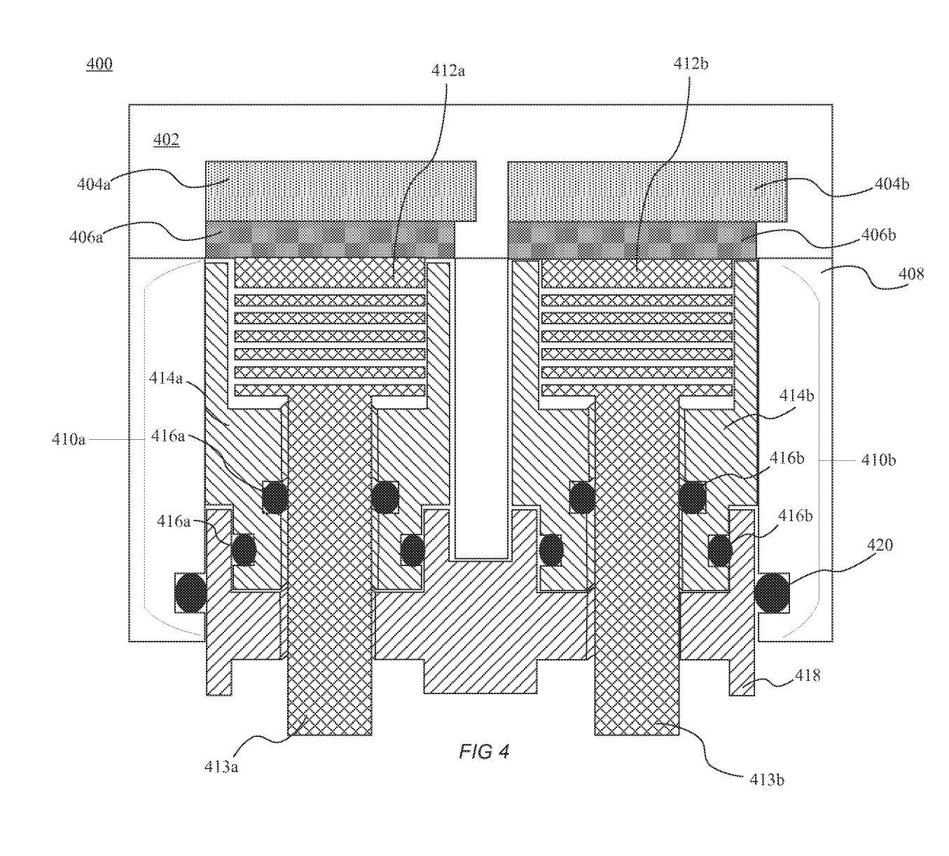

FIG. 4 illustrates a block diagram showing a cut-away view of another example heated platen 400. As depicted, the heated platen 400 includes a dielectric plate 402 having a first heating element 404a and a second heating element 404b, as well as corresponding terminals 406a and 406b disposed therein. The dielectric plate 402 is disposed on an interface plate 408. First and second electrical contact assemblies 410a and 410b are disposed within the interface plate 408 and configured to provide electrical connection to the terminals 406a and 406b respectively. It is to be appreciated that FIG. 4 illustrates only a portion of the heated platen 400. More specifically, only one terminal (i.e., the terminal 406a or 406b) for either of the heating elements 404a or 404b is shown. It will be appreciated that the heated platen 400 will include a second terminal and a corresponding electrical contact assembly for each of the heating elements 404a and 404b, which are not shown for purposes of clarity. Furthermore, the heated platen 400 may include additional heating element(s) and corresponding terminals and electrical contact assemblies. It will also be appreciated that the heated platen 400 may include electrodes, for example, which can be used to electrostatically clamp a substrate to the heated platen in the manner described above with respect to FIG. 1B. Such electrodes are also not shown in the current view for purposes of clarity.

As depicted, the electrical contact assemblies 410a and 410b each include a connector pin 412a, b, non-conductive sleeves 414a, b, and O-rings 416a, b. More specifically, the electrical contact assembly 410a includes the connector pin 412a, the non-conductive sleeve 414a and the O-rings 416a. Similarly, the electrical contact assembly 410b includes the connector pin 412b, the non-conductive sleeve 414b and the O-rings 416b. The electrical contact assemblies 410a and 410b share a single electrical connection plug 418, which can be fit into the interface plate 408 and sealed with an O-ring 420. In general, the electrical contact assemblies 410a, 410b are arranged to allow the conduction of electric current from the connection plug 418 to the connector pins 412a, 412b and the terminals 406a, 406b. In some embodiments, current may be conducted from the connection plug 418 directly to the connector pins 412a, 412b. In such applications, a layer of dielectric or other insulating material may be provided between the connection plug 418 and the interface plate 408. In some embodiments, the connection plug 418 may also be non-conductive. In such applications, the connector pins 412a, 412b may be connected to a current source via their respective bottom portions 413a, 413b. In further applications, the non-conductive elements 414a, 414b and the electrical connection plug 418 may be formed from the same non-conductive material (e.g., ceramic, or the like) and even may be formed as a single component.

The connector pins 412a, 412b may have various geometries, which will be described in greater detail below. The O-ring 420 may be provided to seal the electrical connection plug 418 to the interface plate 408. Similarly, the O-rings 416a, 416b may be provided to seal the non-conductive sleeves 414a, 414b to the electrical connection plug 418 and to seal the connector pins 412a, 412b to the non-conductive sleeves 414a, 414b. As depicted, the O-rings 416a, 416b, and 420 may fit within recesses formed in the interface plate 408 and the various components of the electrical contact assemblies. In some exemplary embodiments, the non-conductive sleeves 414a, 414b may be affixed (e.g., crimped, soldered, welded, bonded, or the like) to the bottom portions 413a, 413b of the connector pins 412a, 412b. In such cases, the O-rings 416a, 416b between these pieces may be eliminated.

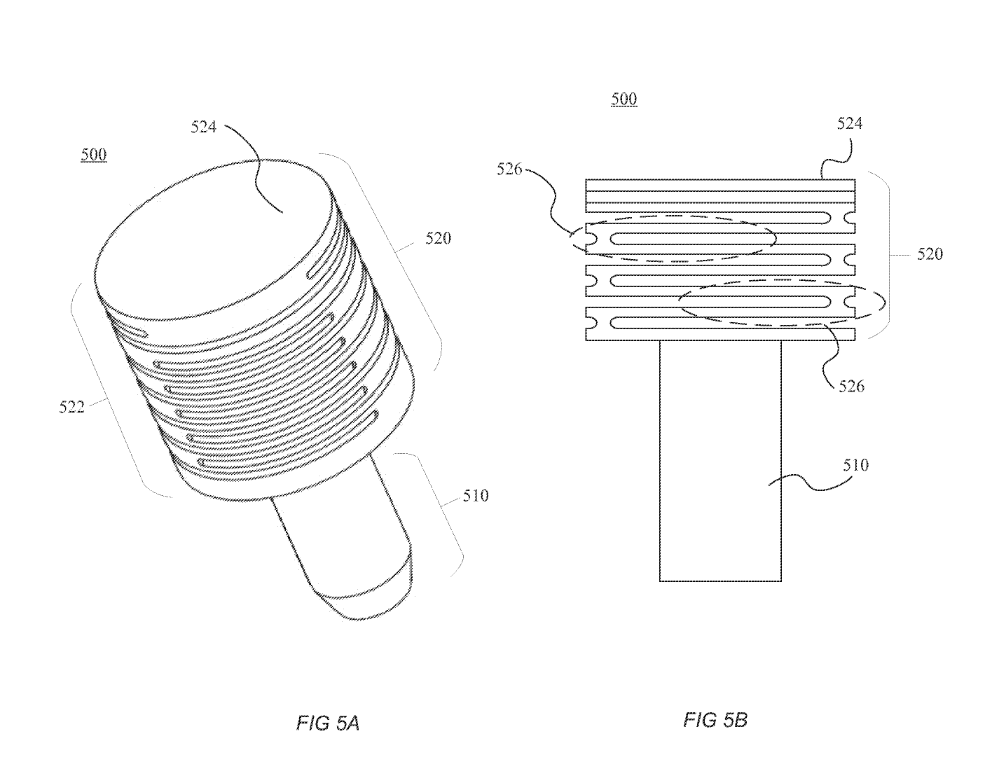

FIGS. 5A-5C, FIG. 6, and FIGS. 7A-7B illustrate various exemplary connector pins that can be used with in the heated platens 122, 200, 300, 400 described above. More specifically, various geometries and arrangements of exemplary connector pins are described for operating at high temperatures. Such connector pins have low thermal conductivity and can maintain electrical contact with associated electrical terminals of the heated platen throughout out a range of operating temperatures are described below.

Referring now to FIGS. 5A-5C, various views of an exemplary connector pin 500 are shown. As can be seen, the connector pin 500 includes generally cylindrical bottom and top portions 510, 520. In the illustrated embodiment, the top portion 520 has an outside diameter that is larger than the outside diameter of the bottom portion. The bottom portion 510 may be a solid cylindrical element having a diameter sized to be received within the electrical connection assemblies depicted in either of FIGS. 2-4. For example, the bottom portion 510 may have a diameter such that the banana clip 216 (FIG. 2) may make electrical connection with the connector pin 500 and retain the connector pin 500 in the electrical connection assembly. Alternatively, the bottom portion 510 may have a diameter such that it may be received within the annular opening in the conductive sleeve 314 of FIG. 3 or the conductive sleeves 414a, 414b of FIG. 4. In other embodiments, the diameter of the bottom portion 510 may be sized so that the conductive sleeves 314, 414a, or 414b may be crimped around the bottom portion 510 and therefore attached to the connector pin 500. It will be appreciated that the bottom portion 510 needn't be cylindrical, but could have other geometric shapes.

The top portion 520 of the connector pin 500 may include a spring structure 522 and an electrical contact surface 524. In the illustrated embodiment, the spring structure 522 is connected at one end to the bottom portion 510 of the connector pin 500, while the electrical contact surface 524 is disposed at an opposite end of the spring structure. The connector pin 500 may have a length “L” while the spring structure 522 may have a spring length “SL.” In the illustrated embodiment, the spring structure 522 runs the length of the top portion 520. It will be appreciated, the top portion 520 can include a non-spring portion, the length of which may be adjusted to provide a desired basing force, as will be described below.

In general, the spring structure 522 may take the form of a compression spring so that the spring structure can be biased to maintain electrical contact between a terminal (e.g., the terminals 206, 306, 406a, or 406b) and the electrical contact surface 524 over a range of operating temperatures. In some non-limiting exemplary embodiments, the range of operating temperatures is 150 to 600° C. And because during operation the dielectric plate 130 may warp and bow as its temperature moves through the range of operating temperatures, the connector pin 500 can be configured to maintain electrical contact between the electrical contact surface 524 and an associated terminal as the dielectric plate warps or bows. In some examples, the spring structure 522 may have a preload force of between approximately 5 and 25 Newtons. In some examples, the spring structure 522 may have a preload force of approximately 10 Newtons.

FIG. 5B shows a first side view of the connector pin 500, including bottom portion 510, spring structure 522 and the electrical contact surface 524. FIG. 5C shows a second side view of the connector pin 500 rotated 90-degrees with respect to the side view of FIG. 5B. As can be seen, the spring structure 522 includes a plurality of leaves 526 that are spaced apart from immediately adjacent leaves by a gap “g.” The plurality of leaves 526 are connected to adjacent leaves via bridge elements 527 disposed, in alternating fashion, on opposite sides of the spring structure. By positioning the bridge elements 527 in this alternating arrangement the spring structure is provided an accordion shape.

Some or all of the bridge elements 527 may include central and/or peripheral cutouts 529, 531. These cutouts 529, 531 can serve to control heat transfer through the spring structure 522 while also providing the spring structure with a desired biasing force.

In some embodiments the connector pin 500 may be formed from a single piece of material. In some examples, the plurality of alternating leaves 526, bridge elements 527 and cutouts 529, 531 may be formed by CNC machining, wire EDM, or other appropriate techniques.

The material may be selected such that the electrical resistance is minimized while the flexural modulus and the thermal conductivity is maximized. Specifically, the material may be selected such that these properties are within desired ranges at the desired operating temperature of the spring connector pin 500. For example, if the connector pin 500 is designed to be operated at 500° C., then the material may be selected such that the flexular modulus, thermal conductivity and resistivity is as desired at 500° C. In some examples, the connector pin 500 may be formed from tungsten, molybdenum, Inconel, titanium or combinations thereof.

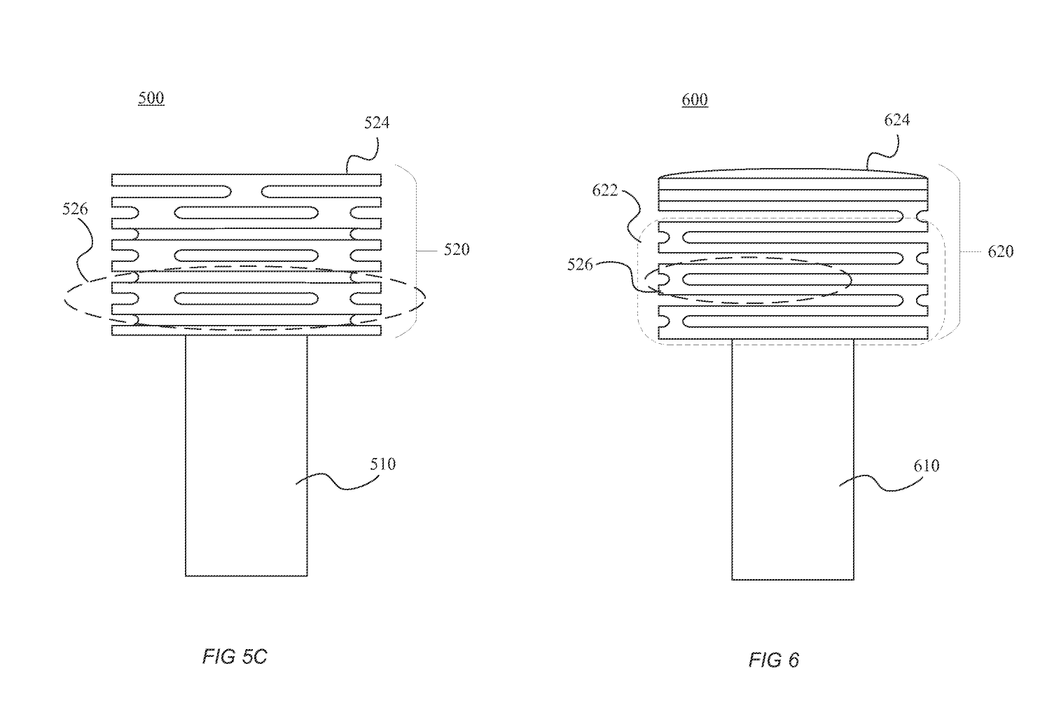

FIG. 6 illustrates a block diagram showing a further exemplary connector pin 600. In general, the connector pin 600 may have a shape, structure and configuration similar to the connector pins described in relation to FIGS. 5A-5C. For example, the connector pin 600 may include a bottom portion 610 and a top portion 620 including a spring structure 622 formed from a plurality of alternating leaves 626. The electrical contact surface 624 of the connector pin 600, however, is domed, as opposed to being generally flat like that depicted in FIGS. 5A-5C. Thus, the electrical contact surface 624 may have a radius of curvature “R,” which in some embodiments may be about 1-inch. Furthermore, the electrical contact surface 624 may be generally convex (as depicted) for the purpose of increasing the area where the electrical contact surface 624 meets the terminal (e.g., the terminals 206, 306, 406a, or 406b) of the heated platen. More particularly, the generally convex shaped electrical contact surface 624 may operate to concentrate the point of electrical contact in one region in order to create a more robust electrical path.

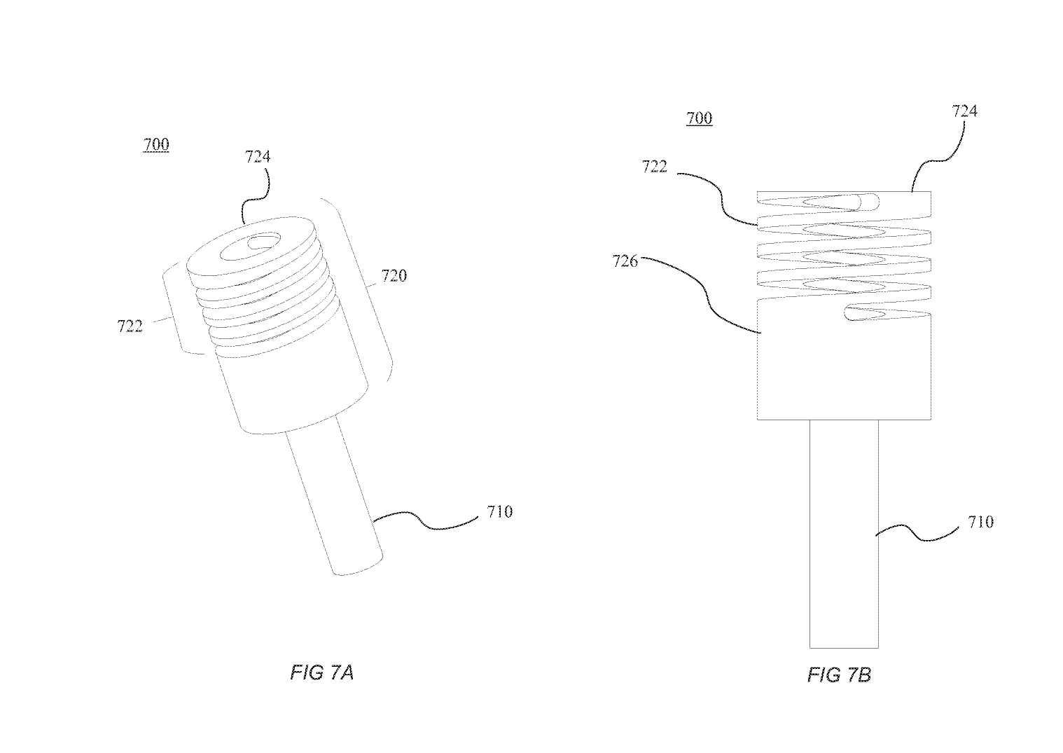

FIGS. 7A-7B illustrate various views of an additional exemplary connector pin 700. As can be seen, the connector pin 700 includes generally cylindrical bottom and top portions 710, 720. In the illustrated embodiment, the top portion 720 has an outside diameter that is larger than the outside diameter of the bottom portion. The bottom portion 710 may have a diameter sized to be received by the electrical connection assemblies depicted in either of FIGS. 2-4. For example, the bottom portion 710 may have a diameter such that the banana clips 216 (FIG. 2) may make electrical connection with the connector pin 700 and retain the connector pin 700 in the electrical connection assembly. Alternatively, the bottom portion 710 may have a diameter such that it may be inserted into the annular opening in the conductive sleeve 314 of FIG. 3 or the conductive sleeves 414a, 414b of FIG. 4. Furthermore, the diameter may be such that the conductive sleeves 314, 414a, or 414b may be crimped around the bottom portion 710 and therefore attached to the connector pin 700. It will be appreciated that the bottom portion 710 needn't be cylindrical, but could have other geometric shapes.

The top portion 720 of the connector pin 700 may include a spring structure 722, and an electrical contact surface 724 disposed at an end of the top portion 720 opposite the bottom portion 710. The spring structure 722 may take the form of a helical coil spring, including a plurality of coil elements 725 separated by spaces 727. The top portion 720 may have a central opening 721 therein, such that the electrical contact surface 724 is generally ring-shaped. Although not shown, it is contemplated that a capped contact surface could be provided (e.g., using an integral or separate cap member) to provide a solid flat or a solid convex contact surface without an opening, or with a reduced size opening.

The connector pin 700 may have an overall length “L,” and the spring structure 722 may have a spring length “SL.” In the illustrated embodiment, the top portion 720 includes a non-spring portion 723 disposed between the spring structure 722 and the bottom portion 710. As will be appreciated, the spring length “SL,” along with other geometric aspects of the spring structure 722 can be adjusted to provide a desired biasing force as will be described below.

As with previous embodiments, the spring structure 722 may be biased to maintain electrical contact between a terminal (e.g., the terminals 206, 306, 406a, or 406b) and the electrical contact surface 724 over a range of operating temperatures. In some examples, the range of operating temperatures is 150 to 600° C. Because the dielectric plate 130 may warp and bow as its temperature moves through the range of operating temperatures, the connector pin 700 can maintain electrical contact with the terminal as the dielectric plate warps or bows. In some examples, the spring structure 722 may have a biasing force of between approximately 5 and 25 Newtons. In some examples, the spring structure 722 may have a biasing force of approximately 10 Newtons.

As noted, the desired biasing force can be obtained by adjusting various of the geometric attributes of the spring structure 722, including the spring length “SL,” the diameter of the opening 721 and the thickness “T” of the coil elements 725. Although the illustrated embodiment shows the coil elements 725 being of substantially equal thickness “T,” it will be appreciated that the coil elements 725 can have different thicknesses. In addition, the opening 721 is shown as being substantially cylindrical, however, it could have a varied cross-sectional shape (e.g., tapered) to provide the spring structure 722 (and resulting connector pin 700) with a desired biasing characteristic.

In some embodiments, the connector pin 700 may be formed from a single piece of material. The material may be selected such that the electrical resistance is minimized while the flexural modulus and the thermal conductivity is maximized. In particular, the material may be selected such that these properties are within desired ranges at a desired operating temperature of the connector pin 700. For example, if the connector pin 700 is designed to be operated at 500° C., then the material may be selected such that the flexular modulus, thermal conductivity and resistivity is as desired at 500° C. In some examples, the connector pin 700 may be formed from tungsten, molybdenum, Inconel, titanium or combinations thereof. In one embodiment the connector pin 700 is formed from a TZM (titanium-zinc-molybdenum) alloy.

FIG. 7B is a side view of the connector pin 700. As depicted, the spring structure 722 includes a number of helical coils 726. In some examples, the helical coils 726 may be formed by cutting helical grooves in the top portion 720 using, for example, CNC machining, wire EDM, or other machining techniques, followed (or alternatively, preceded by) by drilling a hole in the center of the top portion, as depicted in FIG. 7A.

It is to be appreciated, that the methods of forming the connector pins 500, 600, and 700 described above are provided for illustrative purposes only and are not intended to be limiting. Furthermore, the present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. An electrical connection assembly for use in a heated platen having a dielectric plate with a heating element and a terminal electrically connected to the heating element disposed therein, the assembly comprising:
an electrical connection plug; and
a connector pin having a bottom portion and a top portion, the bottom portion for electrically coupling to the electrical connection plug, the top portion having a spring structure, the spring structure configured to maintain electric contact with the terminal of the heated platen by biasing the top portion against the terminal.

2. The assembly according to claim 1, wherein the spring structure comprises a plurality of leaves connected at alternating ends by a plurality of bridge elements.

3. The assembly according to claim 1, wherein the plurality of bridge elements are sized to separate adjacent ones of said plurality of leaves apart by a predetermined gap, and at least one of the plurality of bridge elements includes peripheral or central cutouts for controlling thermal heat transfer through the spring structure.

4. The assembly according to claim 1, wherein the spring structure has a helical coil shape.

5. The assembly according to claim 1, wherein the spring structure includes a central opening.

6. The assembly according to claim 1, wherein the top portion includes a domed electrical contact surface for engaging the terminal, the domed electrical contact surface having a radius of curvature.

7. The assembly according to claim 1, wherein the connector pin comprises a material selected from the group consisting of tungsten, molybdenum, inconel, titanium and combinations thereof.

8. The assembly according to claim 1, further comprising a conductive sleeve disposed between the bottom portion and the electrical connection plug.

9. The assembly according to claim 8, wherein the conductive sleeve is crimped to the bottom portion of the connector pin.

10. The assembly according to claim 8, further comprising a banana clip disposed within the conductive sleeve and configured to retain the connector pin within the sleeve.

11. The assembly according to claim 10, further comprising a nonconductive sleeve disposed around the top portion of the spring connector.

12. An electrical connection assembly for use in a heated platen having a dielectric plate with a heating element and a terminal electrically connected to the heating element disposed therein, the assembly comprising:
an electrical connection plug;
a conductive sleeve disposed within the electrical connection plug; and
a connector pin having a bottom portion and a top portion, the bottom portion disposed within the conductive sleeve, the top portion having a spring structure, the spring structure configured to bias the connector pin against the terminal.

13. The assembly according to claim 12, wherein the spring structure comprises an accordion shape formed by a plurality of leaves connected at alternating ends by a plurality of bridge elements.

14. The assembly according to claim 12, wherein the spring structure comprises a helical coil shape.

15. The assembly according to claim 12, wherein the top portion comprises a ring-shaped contact surface for engaging the terminal.

16. A heated platen comprising:
a dielectric plate including a heating element and a terminal disposed therein, the terminal providing electrical contact to the heating element;
an electrical connection assembly configured to connect the heating element to a power source, the electrical connection assembly comprising:
an electrical connection plug;
a conductive sleeve disposed within the electrical connection plug; and
a connector pin having a bottom portion and a top portion, the bottom portion disposed within the sleeve, the top portion having a spring structure configured to bias the connector pin into engagement with the terminal.

17. The heated platen according to claim 16, wherein the spring structure comprises a plurality of leaves connected at alternating ends by a plurality of bridge elements.

18. The heated platen according to claim 16, wherein the spring structure comprises an accordion shape.

19. The heated platen according to claim 16, wherein the spring structure comprises a helical coil shape.

20. The heated platen according to claim 16, wherein the top portion includes a domed electrical contact surface for engaging the terminal, the domed electrical contact surface having a radius of curvature.
